(19) United States
(12) Patent Application Publication
(10) Pub. No.: US 2008/0234956 A1
(43) Pub. Date: Sep. 25, 2008

(54) METHOD OF CALCULATING STATE VARIABLES OF SECONDARY BATTERY AND APPARATUS FOR ESTIMATING STATE VARIABLES OF SECONDARY BATTERY

(75) Inventors: Satoru MIZUNO, Nishio-city (JP); Shoji Sakai, Nishio-city (JP); Hiroaki Ono, Kariya-city (JP)

Correspondence Address: NIXON & VANDERHYE, PC, 901 NORTH GLEBE ROAD, 11TH FLOOR, ARLINGTON, VA, 22203, US

(73) Assignees: NIPPON SOKEN, INC., Nishio-city (JP); DENSO CORPORATION, Kariya-city (JP)

(21) Appl. No.: 12/049,760

(22) Filed: Mar. 17, 2008

(30) Foreign Application Priority Data
Mar. 19, 2007 (JP) 2007-071292

(51) Int. Cl. G01R 31/36; G06F 19/00

(52) U.S. Cl. 702/63

(57) ABSTRACT

An apparatus for estimating state variables of a secondary battery as an estimation target performs so that a neural network unit studies a true value of a battery temperature, a temperature large value which is larger than the true value of the battery temperature by an approximating temperature sensor detection error, and a temperature small value which is smaller than the true value of the battery temperature by the approximating temperature sensor detection error. After completion of the learning of those values, the neural network unit inputs a battery temperature detected by the temperature sensor, and performs a neural network based calculation to calculate a SOC (state of charge) of the secondary battery. This can drastically increase the calculation accuracy of the SOC of the secondary battery.

### CROSS-REFERENCE TO RELATED APPLICATION

This application is related to and claims priority from Japanese Patent Application No. 2007-71292 filed on Mar. 19, 2007, the contents of which are hereby incorporated by reference.

### BACKGROUND OF THE INVENTION

1. Field of the Invention

The present invention relates to a method of calculating state variables of a secondary battery for a vehicle, and an apparatus for estimating state variables of a secondary battery for a vehicle, in particular, an improved apparatus for calculating internal state variables for a secondary battery using a neural network unit performing a neural network based calculation.

2. Description of the Related Art

It is necessary to calculate or estimate an internal state of a secondary battery with high accuracy mounted on a motor vehicle in views of managing its capacitance and safety. There are various related-art techniques for solving such a requirement. For example, one has disclosed an apparatus for calculating an internal state of a secondary battery, where the internal state includes various values of the secondary battery such as a pseudo opening voltage value, an internal resistance value, a charging ratio, a residual capacitance amount, and the like. However, because the internal state of a secondary battery is a very complicated phenomenon, there is no related art method of estimating internal state variables of the secondary battery with high accuracy.

In order to solve such a problem, Japanese patent laid open publications No. JP H09-243716 and No. JP 2003-249271 have disclosed a neural network based technique with a superior learning function in order to estimate a state of charge (SOC) of a secondary battery.

In such related art techniques disclosed in No. JP H09-243716 and JP 2003-249271 using the method of estimating an internal state of a secondary battery (hereinafter, also referred to a “neural network calculation method”), a current value, a voltage value, a temperature value, which are detected in a secondary battery, and an impedance which is calculated using those detection values are input as input parameters (or input signals), and those input parameters are provided into a neural network in order to estimate a state of charge (SOC) of the secondary battery. It has been found that using such a neural network calculation method can improve its estimation accuracy of the SOC and the like of the secondary battery when compared with other function based internal state calculation methods.

However, a case where there is a secondary battery temperature fluctuation, the estimation accuracy of the related art methods other than the neural network based calculation method are decreased. On the other hand, in a case where there is a secondary battery temperature fluctuation, because a correlation between input information for a neural network and learning information of the neural network is decreased, it is found that the estimation accuracy of the neural network based calculation or estimation is further decreased as a result. In order to solve and eliminate the related art drawback and improve the estimation accuracy of the neural network based calculation or estimation, it is necessary to increase a detection accuracy of a sensor to be used for the estimation. However, this also increases the cost and faces technical difficulties. That is, the accuracy of the neural network based estimation method for estimating state variables of a detection target greatly depends on the sensor accuracy.

### SUMMARY OF THE INVENTION

It is an object of the present invention to provide a method of calculating state variables of the detected target, such as a secondary battery, and an apparatus for estimating state variables such as an internal state of the detected target, based on information gathered using a neural network. The method and apparatus according to the present invention using a neural network can improve estimation accuracy in spite of the presence of a sensor detection error. In particular, the method and apparatus according to the present invention are a neural network based technique capable of preventing a deterioration of estimation accuracy for state variables of a detection target such as a secondary battery.

To achieve the above purposes, the present invention provides a method of calculating state variables of a secondary battery.

The method has a step in which a predetermined neural network learns about the state variables of the secondary battery by inputting a plurality of combinations of the true values of the state variables of the secondary battery. In the method, the state variables of the secondary battery including a secondary battery temperature are input parameters, and an internal state variable of the secondary battery is an output parameter The method has a step of periodically detecting the state variables of the secondary battery, and a step of estimating the output parameter of the secondary battery by inputting detection values of the state variables of the secondary battery to the neural network after the learning. During the learning process, the neural network in the method inputs a temperature small value which is smaller than the temperature true value of the secondary battery, a temperature large value which is larger than the temperature true value of the secondary battery, and the temperature true value into the neural network. In the method, an absolute value of a difference between the temperature small value and the temperature true value, and an absolute value of a difference between the temperature large value and the temperature true value are so set that the absolute value of a difference is approximately equal to an absolute value of a maximum detection error of the temperature sensor.

According to the present invention, in addition to the temperature true value of the secondary battery, following values (a) and (b) are also input into the neural network:

(a) The temperature small value which is approximately smaller than the temperature true value of the secondary battery by a maximum value of the detection error of the temperature sensor; and

(b) The temperature large value which is approximately larger than the temperature true value of the secondary battery by the maximum value of the detection error of the temperature sensor.

The neural network based calculation studies or learns a correlation between the output parameter and the temperature large/small values in addition to a correlation between the output parameter and the temperature true value. It is thereby possible to prevent increasing the estimation error of the neural network caused by the temperature detection error because the decreasing of the estimation error of the output parameter of the neural network caused by shifting the temperature detection value from the temperature true value can be compensated by improved estimation error of the output parameter of the neural network by performing so that the temperature detection value approaches the temperature large value or the temperature small value. According to experimental results of the present invention, it is found that the method of the present invention can effectively reduce an increased amount of the estimation error for the internal state variable of the secondary battery caused by fluctuation of the battery temperature in the neural network based calculation.

The absolute value of a maximum detection error of a commercially available temperature sensor is measured in advance and usually described in its specification. On using an own-making temperature sensor, it is possible to detect a maximum detection error thereof in advance. It is also possible to set a difference value between the temperature true value and the temperature small/large value to a value near the maximum value of the temperature detection error within an operation temperature range of the temperature sensor, for example, it is possible to set the difference value by approximately 10% larger or smaller.

Next, the feature of the present invention will be explained in detail. In general, it is difficult to detect or measure the temperature of a secondary battery for a motor vehicle with high accuracy. It is necessary to directly detect or measure as a battery temperature the temperature of an electrolytic solution or an electrolyte forming the secondary battery in view of a large influence of the battery temperature on ion moving speed in the electrolytic solution and the electrolyte. However, it is difficult to directly detect the temperature of the electrolytic solution or the electrolyte in view of a structure of the secondary battery.

In order to solve and eliminate such a difficulty, there is a method of detecting an outer periphery surface temperature of a housing of a secondary battery or a temperature (or referred to as a battery external temperature) of an external terminal of the secondary battery in order to estimate the temperature (or referred to as a battery internal temperature) of the electrolytic solution or the electrolyte in the secondary battery, or there is a method of calculating a predetermined calculation using the battery external temperature in order to estimate the battery internal temperature of the secondary battery. However, it is not easy for those methods to correctly estimate the internal temperature of the secondary battery. That is, a temperature detection error ΔT is necessarily generated between the detection value (or a detection temperature) of the battery external temperature and the battery internal temperature (as a true value of the battery temperature). For example, it has been found that such a temperature detection error ΔT becomes approximately 10° C. in a typical vehicular secondary battery.

That is, in a situation where a battery temperature is being input (precisely, a battery detection temperature) as an input parameter into a neural network based calculation, such a battery detection temperature involves a large detection error when compared with that of a battery detection voltage value or a battery detection current value as other input parameters. It is accordingly predicted that entering such a battery temperature detection value (as one of more incorrect input parameters) into a neural network based calculation decreases its estimation accuracy.

The present invention has been invented in order to solve such a related art drawback. According to the present invention, during the learning for the neural network, the temperature small value and the temperature large value, which are shifted from the true value of the battery temperature by adding/subtracting a detection error of the temperature sensor, are input in the learning for the neural network based calculation, in addition to the true value of the battery temperature. This means that the neural network based calculation learns or studies the temperature information as the input parameter having a predetermined temperature range of a detection target such as a secondary battery. It is found that the drawback of drastically increasing the output parameter estimation error is drastically decreased in a situation where there is a large detection error of the temperature sensor.

By the way, it is possible to add a voltage value and a current value of the secondary battery in addition to the detection temperature value as state variables of the secondary battery to be used in the learning of the neural network based calculation and the calculation of the output parameter of the secondary battery.

The voltage and current data are a history of the voltage and currents which are sampled during the latest specified time range, or to be precise, they are the set of voltage and current values of the secondary battery. It is preferable to sample the voltage and current simultaneously as the voltage and current pair. It is also possible that the voltage and current pairs are used as a voltage and current history during a latest period of time, and also possible to use an average value of the voltage and current pairs.

It is also possible to apply various types of well-known neural network based calculations to the method and apparatus according to the present invention. Using a microcomputer having a program of performing such neural network based calculations can realize the neural network based method and apparatus.

The neural network is composed of an input layer, an output layer, and an intermediate layer having plural stages placed between the input layer and the output layer. The input layer inputs state variables of a secondary battery (or a storage battery). The output layer outputs a charged state variable of the secondary battery for example. The intermediate layer having plural stages placed between the input layer and the output layer and each stage calculates predetermined calculations under predetermined stages. One stage in the intermediate layer is connected to a previous stage in the intermediate layer or connected to the input layer with a predetermined weight, and one stage is further connected to a following stage of the intermediate layer or connected to the output layer with a predetermined weight. Each connection or combination coefficient between the input layer and the intermediate layer or the intermediate layer and the output layer is stored as a combination coefficient memory table into a memory in the apparatus.

Still further, it is possible to input, as state variables of the secondary battery for use in performing the learning for the neural network based calculation or to input for the output parameter calculation, a polarization correlation value having a correlation between an internal resistance, an opening voltage, a polarization amount of the secondary battery which are calculated using various well known equations.

It is possible to calculate the internal resistance and the opening voltage of the secondary battery using past voltage and current data items by approximation calculation method of the related art.

It is also possible to use the temperature detection value of the secondary battery as a compensated detection value which has been compensated by a predetermined compensation calculation before inputting it into the neural network based calculation after completion of the learning. That is, when considering from a viewpoint where the temperature sensor is mounted on an outer peripheral surface (including an external terminal surface) of the secondary battery, the temperature detection values is a value of a function depending on a surrounding temperature of the secondary battery, a heat conductive resistance and a heat capacitance of a passage from a heating part in the secondary battery and the outer peripheral part of the secondary battery, and a heat conductive resistance and a heat capacitance of a passage from the outer periphery surface of the secondary battery and a surrounding heat source. It is therefore possible to compensate the temperature detection value with some accuracy by calculating a heat discharging circuit model of a secondary battery obtained by considering the above function. Thus, the compensated temperature value is used as the compensated detection value.

In the method as another aspect of the present invention, in the learning by the neural network, the number of inputs of the temperature true value into the neural network is substantially larger than the number of inputs of the temperature small value and the temperature large value to the neural network.

Because the detection value detected by the temperature sensor has a larger provability to approach a temperature true value when compared with a provability to approach the temperature true value of the temperature small value and of the temperature large value during the learning of the neural network based calculation, it is possible to decrease the estimation error of the output parameter when compared with the case in which the temperature true value, the temperature small value, and the temperature large value are equally input into the neural network based calculation during the learning for the neural network based calculation.

In the method as another aspect of the present invention, the state variables of the secondary battery include an opening voltage ratio in addition to the secondary battery temperature. This is preferable to increasing the detection accuracy of the temperature sensor.

In the above explanation, the state variable detected from the secondary battery as a detection target by the sensor is a battery temperature, the neural network based calculation learns or studies in advance the relationship between a value obtained by adding/subtracting a predetermined detection error value, which is estimated in the secondary battery, to/from the true value of the secondary battery, and it is thereby possible to prevent decreasing a correlation state between the detection state variable and the target state variable in the learning of the neural network.

Still further, when the neural network based calculation inputs as an input parameter a function value obtained from a detected state variable, the detection error of the detected state variable, as a matter of course, generate a function value error. In a case where the function value of the detected state variable is input as the input parameter to the neural network based calculation, the neural network based calculation inputs in advance a relationship between a function value, obtained by performing adding/subtracting a detection state variable to/from a predetermined detection error, and a true value of the state variable of the secondary battery when the function value is input as the input parameter into the neural network based calculation. It is thereby possible to prevent the deterioration of the correlation between the function value and the state variable in the leaning of the neural network based calculation caused by the fluctuation of the function value which is generated by the detection error of the detected state variable.

It is possible to use, as a function value, an internal resistance, an opening voltage, a polarization amount and the like.

The technique of the method and apparatus according to the present invention described above which is capable of decreasing the estimation error of the neural network based calculation caused by the sensor detection error can be effectively applied to various detection targets other than the secondary battery.

In accordance with another aspect of the present invention, where the detection target is expanded, there is provided an apparatus for estimating state variables of an estimation target based on a neural network based calculation. The apparatus is comprised of a sensor and a neural network unit. The sensor is configured to detect a state variable of the estimation target and to output the detected state variable as an output signal of the sensor. The neural network unit is configured to input one of the output signal of the sensor and a function value of a predetermined function of the output signal of the sensor, to perform a neural network based calculation, and to output a predetermined state variable of the estimation target as an output parameter thereof which is different from the detection state variables of the estimation target. In particular, before executing the neural network calculation by the apparatus, the neural network unit studies or learns plural times a combination of the output signal of the sensor or a true value of the function value of the predetermined function of the output signal of the sensor and a true value of the predetermined state variable of the estimation target, and further learns a relationship between the true value of the state variable of the estimation target and a value obtained by adding/subtracting a predetermined sensor detection error value to/from one of the output signal and the function value of the predetermined function of the output signal of the sensor.

The true value of the output signal or the function value is a true value of an output signal of the sensor or a function value as an output variable of a predetermined function which inputs the true value of the output signal of the sensor. The true value of the above function value when the output signal of the sensor is a true value is obtained by inputting the true value of the output signal of the sensor to a functional equation (or a map) which is stored in a memory in advance.

The predetermined sensor detection error amount is determined based on a well-known detection accuracy of the sensor. For example, it is possible to use as the predetermined sensor detection error amount an absolute value of the maximum value of an error obtained by a well-known detection accuracy of the sensor or a value within a range of 50 to 100% of the absolute value. It is possible to prevent deterioration of the correlation between the input parameter and the output parameter, which is caused by the detection error of the sensor, using a simple method in the neural network after completion of the learning by the detection error of the sensor.

### BRIEF DESCRIPTION OF THE DRAWINGS

A preferred, non-limiting embodiment of the present invention will be described by way of example with reference to the accompanying drawings, in which:

FIG. 1 is a circuit block diagram showing a configuration of an apparatus for calculating state variables of a secondary battery as a detection target according to an embodiment of the present invention;

FIG. 2 is a view showing a basic configuration of a neural network based calculation to be used in the apparatus for calculating the state variables of the secondary battery shown in FIG. 1;

FIG. 3 is a flow chart showing a learning step of the neural network based calculation shown in FIG. 2;

FIG. 4 is a view showing the learning step performed in the neural network unit;

FIG. 5 is an explanatory view showing a procedure of obtaining a pseudo opening voltage of a secondary battery;

FIG. 6 is a view showing a characteristic relationship between a pseudo opening voltage ratio, an electrolytic solution temperature, and a state of charge (SOC) of a secondary battery;

FIG. 7 is a view showing the learning step and the SOC calculation performed using a neural network based calculation of a reference example;

FIG. 8 is a characteristic view of SOC errors at each temperature in the neural network based calculation after completion of the learning step shown in FIG. 7;

FIG. 9 is a block diagram showing the learning step of the neural network unit in the apparatus and the SOC calculation by the neural network unit after completion of the learning step according to the embodiment described above;

FIG. 10 is a characteristic view of SOC errors at each temperature in the neural network based calculation after completion of the learning step shown in FIG. 9; and

FIG. 11 is a view showing the detection results of the SOC detection errors of various type storage batteries, which were calculated by the neural network unit of the apparatus according to the embodiment and the reference example.

### DETAILED DESCRIPTION OF THE PREFERRED EMBODIMENTS

Hereinafter, various embodiments of the present invention will be described with reference to the accompanying drawings. In the following description of the various embodiments, like reference characters or numerals designate like or equivalent component parts throughout the several diagrams.

### Embodiment

A description will be given of a method of calculating state variable of a secondary battery and an apparatus of estimating an internal state variable of the secondary battery using a neural network based calculation.

### (Principal of Calculating State Variables of a Secondary Battery Using a Neural Network Based Calculation)

A description will now be given of principal of calculating state variables of a secondary battery using a neural network based calculation.

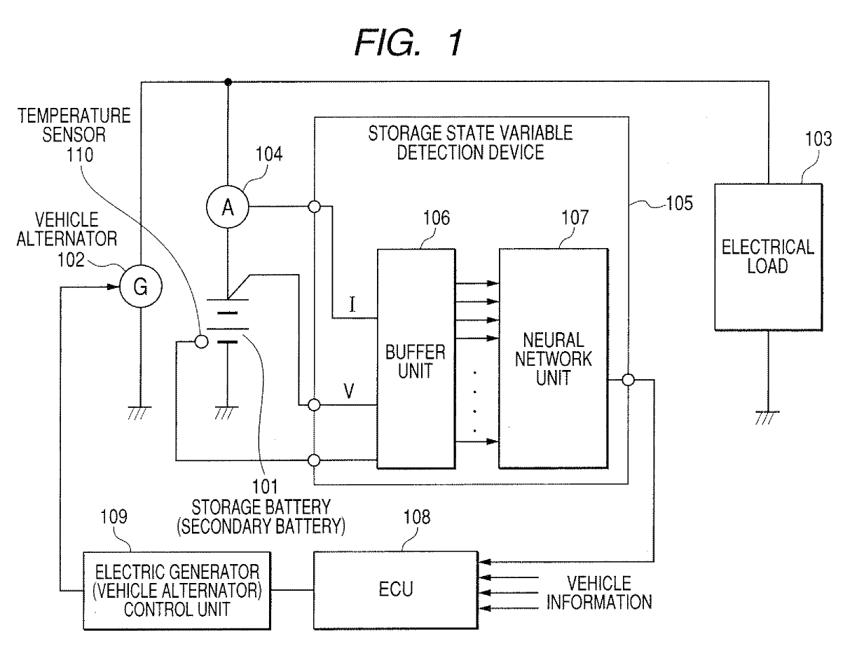

FIG. 1 is a circuit block diagram showing a configuration of the apparatus for calculating state variables of a secondary battery using the neural network based calculation according to the present invention.

First, a circuit configuration of the apparatus for calculating state variables of the second battery according to the present invention will be explained.

In FIG. 1, reference number 101 designates a secondary battery or a storage battery as a detection target such as a lead acid secondary battery, a nickel metal alloy (NiMH) secondary battery, and a lithium secondary battery. Hereinafter, the secondary battery is referred to as the “Storage battery”. Reference number 102 denotes a vehicle alternator driven by an internal combustion engine (not shown) in a motor vehicle (not shown), 103 indicates one or more electrical loads which are built in the motor vehicle, 104 designates a current sensor for detecting a charge/discharge current of the battery 101, 105 designates a storage battery state (or condition) variable detection device, 106 indicates a buffer unit, and 107 designates a neural network unit for executing a neural network based calculation. The buffer unit 106 inputs various detection signals regarding a voltage, a current, and a temperature of the storage battery 101 detected by various types of sensors. The buffer unit 106 stores those values corresponding the detection signals into a memory (not shown) therein. Those values transferred from the detection sensors and the already-stored values in the memory are transferred to the neural network unit 107 for executing the neural network based calculation.

The neural network unit 107 inputs those input values transferred from the buffer unit 106, and executing the neural network based calculation to calculate a state of charge (SOC) of the storage battery 101 based on those input values. The neural network unit 107 transfers the SOC as the calculation result to an engine control unit (ECU) 108. The ECU 108 receives the SOC transferred from the neural network unit 107, and calculates an electrical power generation amount of the vehicle alternator 102 based on the SOC, other engine state values, and a vehicle condition values. The ECU 108 then transfers the calculated electric power generation amount to an electric power generator (vehicle alternator) control unit 109. As shown in FIG. 1, the ECU 108 receives vehicle information transferred from other devices (not shown).

The electric power generator control unit 109 receives the calculated electric power generation amount and transfers to the vehicle alternator 102 an instruction to generate the electrical power corresponding to the electric power generation amount. In FIG. 1, reference number 110 designates a temperature sensor for detecting a temperature of the storage battery (or a secondary battery) 101. For example, the temperature sensor 110 is fixedly attached onto an outer periphery surface of the storage battery 101.

### (Basic Operation of the Buffer Unit 106 and the Neural Network Unit 107)

In fact, it is possible to realize the buffer unit 106 and the neural network unit 107 using one or more software programs to be executed in a microcomputer system. It is also possible to realize the buffer unit 106 and the neural network unit 107 using one or more dedicated hardware circuits.

The buffer unit 106 regularly inputs the detection signals regarding a voltage value, a current value, and a temperature value of the storage battery 101, and then stores those values in the memory (not shown). The buffer unit 106 then calculates an opening voltage Vo of the storage battery 101 based on previous voltage and current pairs of a predetermined number using a well-known formula. The neural network unit 107 inputs the opening voltage Vo transferred from the buffer unit 106 in addition to those values. It is also possible that the neural network unit 107 inputs and stores an internal resistance R of the storage battery 101 which is calculated by and transferred from the buffer unit 106.

A description will now be given of a simple calculation method of calculating the opening voltage Vo and the internal resistance R of the storage battery 101.

First, an approximation linear line L is made based on a well-known method of least square using the predetermined number of voltage and current pairs, where the approximation linear line L shows a relationship between a voltage V and a current I.

Next, an intercept (which becomes an opening voltage Vo) and a slope (which becomes an internal resistance R) of the approximation linear line L are calculated every inputting a voltage and current pair. Those opening voltage Vo and internal resistance R are output every calculation. Because the method of calculating the opening voltage Vo and the internal resistance R using the approximation linear line L is well-known matter, the further explanation thereof is omitted here. It is also possible to calculate a polarization correlation amount as an electrical value regarding the polarization in the storage battery 101 using the voltage and current pair, and to output the polarization correlation amount as an input parameter into the neural network unit 107.

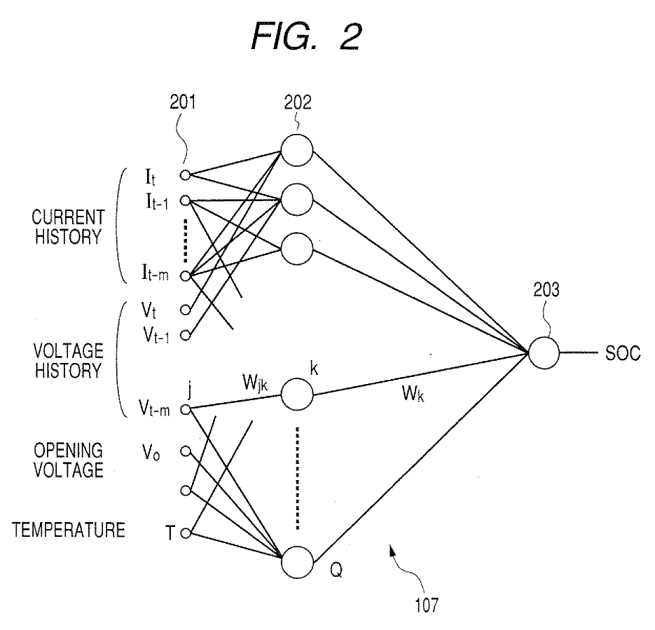

Next, a description will now be given of the neural network based calculation with reference to the block diagram shown in FIG. 2.

Although the neural network unit 107 after completion of the leaning according to the present invention is composed of a three stage hierarchy structure of a feed-forward type based on Error back propagation algorithm. The present invention is not limited by this type.

The neural network unit 107 is composed mainly of an input layer 201, an intermediate layer 202, and an output layer 203. The neural network unit 107 is realized using software which is carried out every predetermined calculation interval. That is, because the neural network unit 107 is realized by software calculation executed by a microcomputer circuit (not shown), the circuit configuration shown in FIG. 1 is a schematic structure in view of function. In FIG. 2, each input cell 201 in the input layer 201 independently inputs an input parameter and outputs the input one to all of calculation cells in the intermediate layer 202. Each calculation cell in the intermediate layer 202 performs the neural network based calculation for the input data items provided from each input cell in the input layer 201, and outputs the calculation results to the output cell forming the output layer 203. The output cell in the output layer 203 outputs the state of charge (SOC) of the storage battery, for example, to the ECU 108 shown in FIG. 1.

### (Leaning Method of the Neural Network Unit 107)

A description will now be given of the learning method performed by the neural network unit 107 shown in FIG. 2.

FIG. 2 is a view showing a basic configuration of a neural network based calculation in the neural network unit 107 in the apparatus for calculating state variables of the storage battery shown in FIG. 1.

When an input data item for j-cell in the input layer 201 of the neural network unit 107 is Ij, and a combination coefficient between j-cell in the input layer 201 and k-cell in the intermediate layer 202 is Wjk, input data item for k-cell is expressed as follows.

INPUT k(t)=Σ(Wjk*Ij), where j=1 to 2m+3.

The output signal from k-cell in the intermediate layer 202 is expressed as follows.

OUT k(t)=f(x)=f(INPUT k(t)+b), where b is a constant.

f (INPUT k(t)+b) is a non-linear function called to as the “sigmoidal function” using INPUT k(t)+b as an input parameter.

The sigmoidal function is defined by the following expression.

f(INPUT k(t)+b)=1/(1+exp(−(INPUT k(t)+b))).

When a combination coefficient between k-cell in the intermediate layer 202 and the output cell in the output layer 203 is Wk, the input signal INPUT o(t) to the output layer 203 is expressed as follows.

INPUT o(t)=ΣWk*OUT k(t), k=1 to Q,

where Q is the number of cells in the intermediate layer 202.

The output signal at time t can be expressed as follows.

OUT soc(t)=L*INPUT o(t), where L is a linear constant parameter.

Through the description of the present invention, the learning step is to optimize the combination coefficient between cells so that an error between a final output OUT soc(t) at time t and a teacher signal (that is, true value tar (t)) is decreased to a minimum value, where the teacher signal (that is, true value tar (t)) has been measured in advance. The output OUT soc (t) is an output parameter to be output by the output layer 203, and in this case, the output OUT soc (t) is the SOC of the storage battery at timing t.

Next, a description will now be given of the updating method of each combination coefficient.

Updating the combination coefficient Wk between k-cell in the intermediate layer 202 and the output cell in the output layer 203 is expressed as follows,

Wk=Wk+ΔWk.

The value ΔWk is expressed as follows.

$$\begin{matrix}Δ Wk = η * \partial Ek / \partial Wk \\ = η * \{ OUT ( t ) - tar ( t ) \} * \{ \partial OUTsoc ( t ) / \partial Wk \} \\ = η * \{ OUTsoc ( t ) - tar ( t ) \} * L * \{ \partial INPUT ∘ ( t ) / \partial Wk \} \\ = η * L * \{ OUTsoc ( t ) - tar ( t ) \} * OUTk ( t ) ,\end{matrix}$$

where η is a constant,

Ek is a value indicating an error between the teacher data (or the true value tar (t)) and the output of the neural network unit 107. Ek can be expressed as follows.

Ek=[OUT(t)−tar(t)]×[OUT(1)−tar(t)]/2.

Next, a description will now be given of the updating routine of the combination coefficient Wjk between k-cell in the intermediate layer 202 and j-cell in the input layer 201.

The updating for the combination coefficient Wjk can be expressed as follows.

Wjk=Wjk+ΔWjk.

ΔWjk is expressed as follows.

$$\begin{matrix}Δ Wjk = - η * \partial Ek / \partial Wjk \\ = - η * \{ \partial Ek / \partial INPUTk ( t ) \} * ( \partial INPUTk ( t ) / \partial Wjk \} \\ = - η * \{ \partial Ek / \partial OUTk ( t ) \} * \{ \partial OUTk ( t ) / \partial INPUTk ( t ) \} * Ij \\ = - η * \{ \partial Ek / \partial OUTsoc ( t ) \} * \{ \partial OUTsoc ( t ) / \partial INPUT ∘ \} * \\ \{ \partial INPUT ∘ / OUTk ( t ) \} * {f}^{′} ( INPUTk ( t ) + b ) * Ij \\ = - η * ( OUTsoc ( t ) - tar ( t ) ) * L * Wk * {f}^{′} ( INPUTk ( t ) + b ) * Ij \\ = - η * L * Wk * Ij * ( OUTsoc ( t ) - tar ( t ) ) * {f}^{′} ( INPUTk ( t ) + b ) ,\end{matrix}$$

where f′ (INPUTk(t)+b ) is a differential value of the propagation function f(INPUTk(t)+b).

The SOC of the storage battery is calculated again and again at the output OUTsoc(t), namely, at timing t using the newly-updated combination coefficients Wk and Wjk. This procedure is repeatedly continued until the value of the error function Ek becomes not more than a predetermined infinitely small value.

Thus, the neural network unit 107 performs the learning by continuously updating the combination coefficient until the value of the error function Ek becomes not more than the predetermined value.

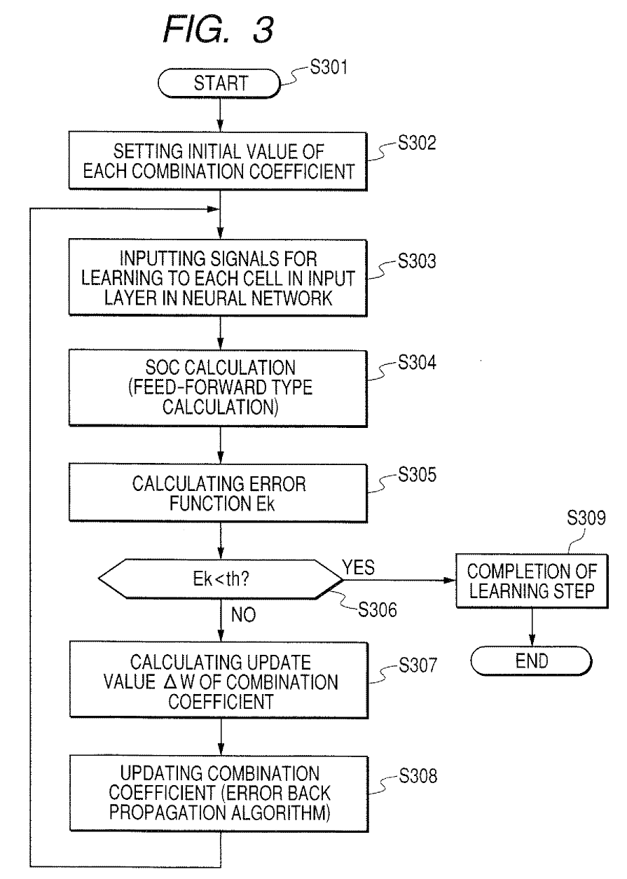

FIG. 3 is a flow chart showing the above learning step of the neural network based calculation.

Although the neural network unit 107 outputs the SOC (state of charge) of the storage battery 101, the present invention is not limited by this. For examples it is possible that the neural network unit 107 outputs a SOH (state of health) of the storage battery 101 instead of the SOC.

First, an optimum initial value is input into the neural network unit 107 (step S302). It is, for example, possible to determine the optimum initial value using random numbers.

Next, each input signal for the leaning is input into each cell in the input layer 201 in the neural network unit 107 (step S303). The neural network unit 107 performs the neural network based calculation of those input signals using the initial value of the combination coefficient in order to calculate the SOC of the storage battery 101 as the output parameter of the neural network unit 107 (step S304).

The error function Ek is calculated based on the above method (step S305). It is then judged whether or not the function value of the error function Ek is smaller than the predetermined infinitely small value “th” (step S306).

When the judgment result indicates that the function value of the error function Ek exceeds the predetermined infinitely small value “th”, the updating value ΔW of each combination coefficient defined in the previous learning step is calculated (step S307), and each combination coefficient is updated (step S308).

Next, another input signal for the learning step is input in each cell of the input layer 201 in order to re-calculate the SOC (step S309). The value of the error function Ek is evaluated again. When the evaluation result indicates that the value of the error function Ek is lower than the predetermined infinitely small value “th”, it is judged that the learning step in the neural network unit 107 is completed.

When the evaluation result indicates that the value of the error function Ek is not lower than the predetermined infinitely small value “th”, the combination coefficient is updated and the SOC is then calculated again and again. The value of the error function Ek is further evaluated. Those steps are repeatedly executed until the value of the error function Ek is not more than the predetermined infinitely small value “th”.

As described above, it is possible to efficiently estimate the SOC of the storage battery 101 using the neural network unit 107 capable of learning the previous relationship between the input signals and the output signal such as the SOC of the storage battery 101.

### (Input Parameters for the Neural Network Unit 107 in the Apparatus According to the Present Invention)

Next, a description will now be given of a case which uses only a pseudo opening voltage and an electrolytic solution temperature of the storage battery 101 as the input parameters for the learning step and the neural network based calculation for the SOC of the storage battery 101, performed after completion of each learning step executed by the neural network unit 107. The following explanation uses the above-described same method or procedure of the learning step and the SOC calculation step after completion of each learning step.

That is, in this case, the pseudo opening voltage ratio and electrolytic solution temperature of the storage battery 101, which have been obtained in advance, are input into the neural network unit 107 plural times in order that the neural network unit 107 performs the learning step plural times. After each learning step, the neural network unit 107 inputs only the pseudo opening voltage ratio and electrolytic solution temperature of the storage battery 101 for performing the SOC based on the neural network based calculation.

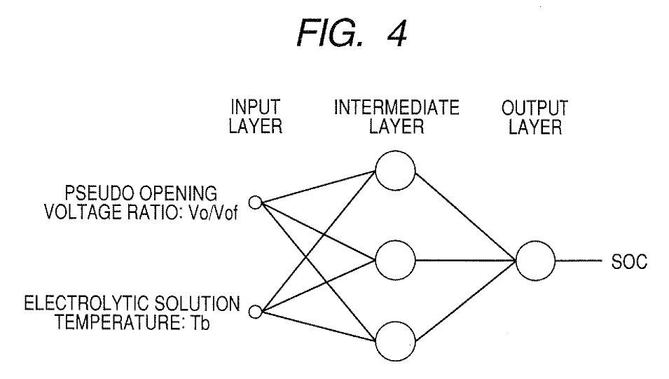

FIG. 4 is a view showing the learning step performed in the neural network unit 107.

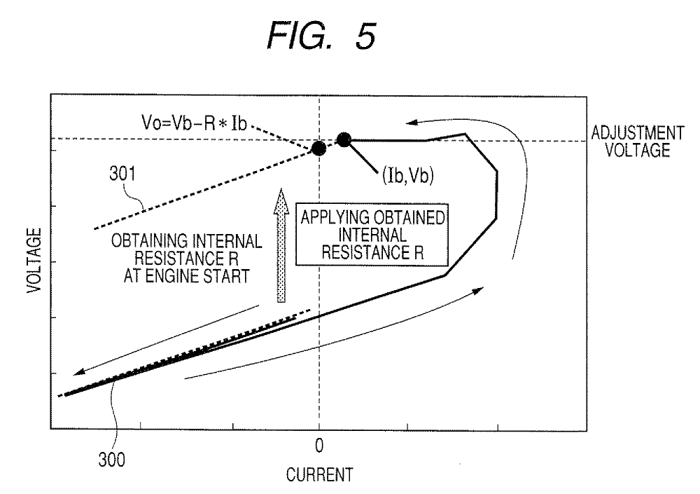

The method of calculating the pseudo opening voltage is explained with reference to FIG. 5. FIG. 5 is an explanatory view showing the procedure of obtaining the pseudo opening voltage ratio of the storage battery (or the secondary battery) 101.

The pseudo opening voltage ratio is defined as a ratio between a pseudo opening voltage Vof at a specific SOC (for example, 90% of SOC) and a pseudo opening voltage at each SOC value.

First, an internal resistance R (which corresponds to a slope of the approximation straight line of a current and voltage pairs) is calculated based on the current and voltage characteristic line 300 when a large current is discharged at the engine start. (see FIG. 5). After completion of this calculation, a constant voltage charging for the storage battery 101 is performed for 60 seconds under a usual constant voltage electrical generation control so that the electrical generation voltage is equal to a predetermined adjustment voltage.

Next, a current and voltage characteristic line 301 is obtained, in which the slope of the line 301 is the internal resistance R which is previously calculated, and the line 301 passes through a coordinate designated by the current value 1b and the voltage value Vb immediately following the completion of the constant voltage charging. The pseudo opening voltage value Vo is calculated using the current and voltage characteristic line 301 (Vo=Vb−R*Ib).

Although it is preferred to calculate the pseudo opening voltage value immediately following the engine start at which a current value is drastically changed, the present invention is not limited by this.

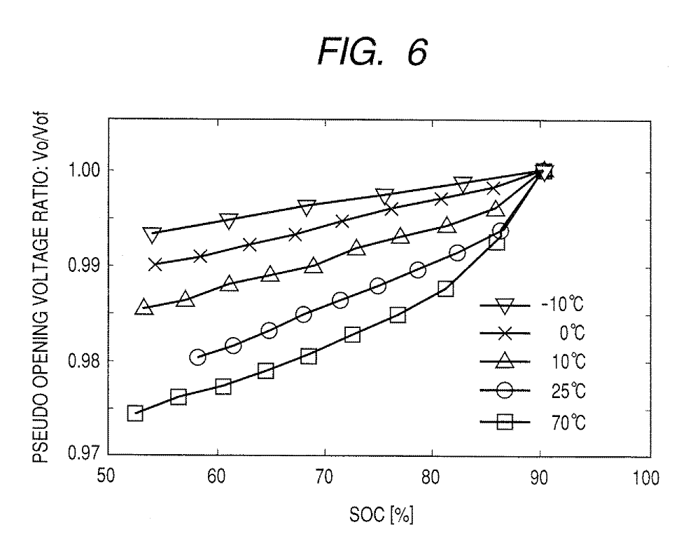

FIG. 6 is a view showing a characteristic relationship between the electrolytic solution temperature, the pseudo opening voltage ratio, and the state of charge (SOC) of the secondary battery. It is understood from FIG. 6 that the relationship between the pseudo opening voltage ratio and the SOC is changed according to the electrolytic solution temperature of the storage battery 101. Further, it is possible to estimate the SOC of the storage battery 101 when the pseudo opening voltage ratio and the electrolytic solution temperature are obtained using the relationship shown in FIG. 6.

The present invention uses an electrolytic solution temperature estimation value which is estimated using a temperature value as the electrolytic solution temperature detected by the temperature sensor, in the SOC calculation performed by the neural network unit 107, as described later in detail. This estimation is performed in order to reduce an error between the detection temperature value of the temperature sensor fixedly attached onto the outer periphery surface of the storage battery 101 and the electrolytic solution temperature.

A description will now be given of a method of obtaining the electrolytic solution estimation temperature value Tp using the detection temperature value Td. The estimation temperature value Tp is a weighted average value (of 1/1024 times) of the detection temperature values Td, which is detected every 10 seconds. The weighted average value of the detection temperature values Td is obtained by the following equation.

Tp(n)=Tp(n−1)*1023/1024+Td*1/1024.

### (Reference Example)

Next, a description will now be given of a reference example which uses a true value as an electrolytic solution temperature and estimates a SOC of the storage battery by the neural network unit 107, where the true value as an electrolytic solution temperature is one of the input parameters for the neural network unit 107, and the electrolytic solution temperature estimation value is estimated using the detected temperature values detected by the temperature sensor as the electrolytic solution temperature in the SOC calculation.

First, the learning step in the reference example will be explained.

In the learning step in the reference example, the neural network unit 107 inputs the electrolytic solution temperature value (as the true value) for each of the batteries A, B, C, D, and E, as shown in the following Table 1, and inputs an electrolytic solution temperature, directly detected in the electrolytic solution using a thermoelectric couple and the like, as the electrolytic solution temperature estimation value for each battery.

The batteries A, B, C, D, and E in the following Table 1 have a different electrolytic solution temperature in the same storage battery.

TABLE 1

| | Electrolytic | Electrolytic solution | |
|---|---|---|---|
| | solution | temperature | Input |
| | temperature | estimation error | value |
| Battery | [° C.] | [° C.] | [° C.] |
| A | −10 | 0 | −10 |
| B | 0 | 0 | 0 |
| C | 10 | 0 | 10 |
| D | 25 | 0 | 25 |
| E | 70 | 0 | 70 |

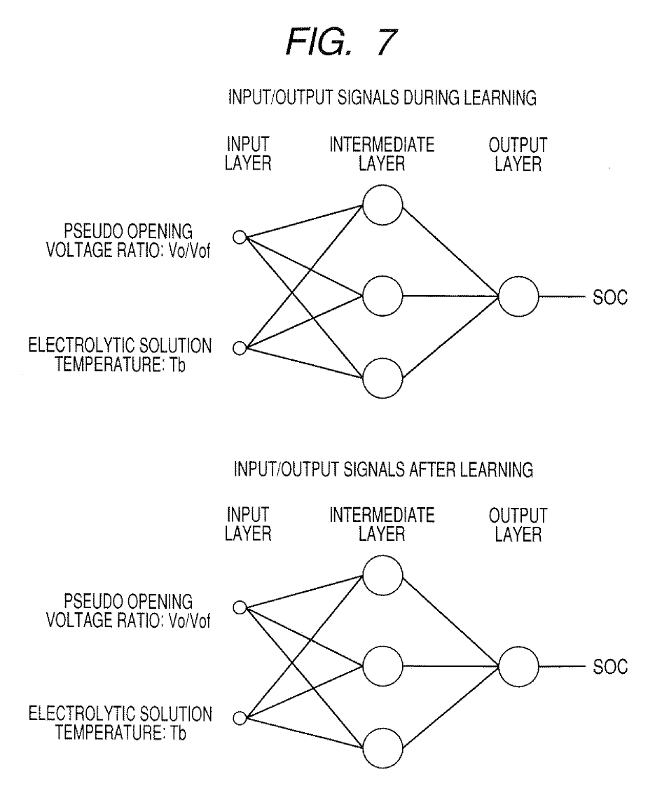

FIG. 7 is a view showing the learning step and the SOC calculation step performed using the neural network based calculation of the reference example.

### (SOC Calculation After Completion of the Learning Step)

As a natural consequence, after each learning step, the calculated pseudo opening voltage ratio which is obtained in the previous learning step is input into the input cells in the input layer 102. At the same time, after the learning step, the electrolytic solution temperature estimation value estimated from the detection temperature value obtained by the temperature sensor is input into the input cells in the input layer 102 to which the electrolytic solution temperature of the storage battery 101 is input during the learning step.

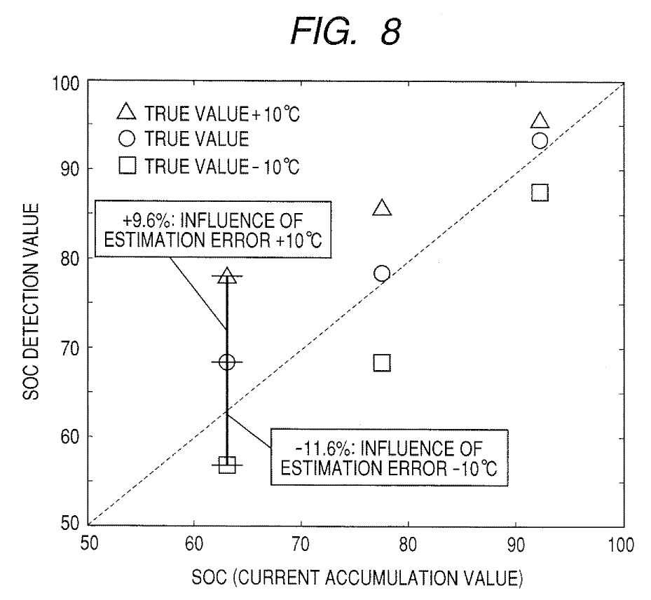

Next, a description will now be given of the SOC detection error when the neural network unit 107, after completion of the learning step, inputs the true value, the true value +10° C., and the true value −10° C. as the electrolytic solution temperature value with reference to FIG. 8.

A same pseudo opening voltage ratio is input into the neural network unit 107 for the true value, the value of the true value +10° C., and the value of the true value −10° C.

In FIG. 8, reference character “◯” indicates the true value, “Δ” denotes the value of the true value +10° C., and “□” designates the value of the true value −10° C.

The pseudo opening voltage ratio obtained every electrolytic solution temperature value is input into the neural network unit 107 as the input parameter.

In FIG. 8, the horizontal line indicates the SOC value obtained by the current accumulation, and the vertical line denotes the SOC detection value obtained by the neural network unit according to the present invention and by the neural network unit according to the reference example.

It can be understood from FIG. 8 that the SOC detection value becomes +9.6% up when the temperature detection value having an estimation error which is larger by 10° C. than that when the electrolytic solution temperature estimation value is correctly input to the neural network unit 107 (in case of inputting the true value of 0° C.). Further, the SOC detection value becomes −11.6% down when the temperature detection value having an estimation error which is smaller by 10° C. than that when the electrolytic solution temperature estimation value is correctly input to the neural network unit 107.

### Embodiment

Next, a description will now be given of an embodiment of the learning step by the neural network unit 107 using the true value of the electrolytic solution temperature, a larger temperature value (=true value +10° C.) from the true value of the electrolytic solution temperature, and a smaller temperature value (true value 10° C.) from the true value of the electrolytic solution temperature. In this case, an available real electrolytic solution temperature estimation value is used, like the reference example. Table 2 shows the electrolytic solution temperature as one input parameter to be input into the neural network unit 107 during the learning step in the embodiment. The batteries A, B, C, D, and E in the following Table 2 have a different electrolytic solution temperature in the same storage battery,

TABLE 2

| | Electrolytic | Electrolytic solution | |
|---|---|---|---|
| | solution | temperature | Input |
| | temperature | estimation error | value |
| Battery | [° C.] | [° C.] | [° C.] |
| A | −10 | 0 | −10 |
| B | 0 | 0 | 0 |
| C | 10 | 0 | 10 |
| D | 25 | 0 | 25 |
| E | 70 | 0 | 70 |
| *A | −10 | 10 | 0 |
| *B | 0 | 10 | 10 |
| *C | 10 | 10 | 20 |
| *D | 25 | 10 | 35 |
| *E | 70 | 10 | 80 |
| *A | −10 | −10 | −10 |
| *B | 0 | −10 | −10 |
| *C | 10 | −10 | 0 |
| *D | 25 | −10 | 15 |
| *E | 70 | −10 | 60 |

*A, *B, *C, *D, and *E: Adding data obtained by adding true value of electrolytic solution temperature and ±estimation error.

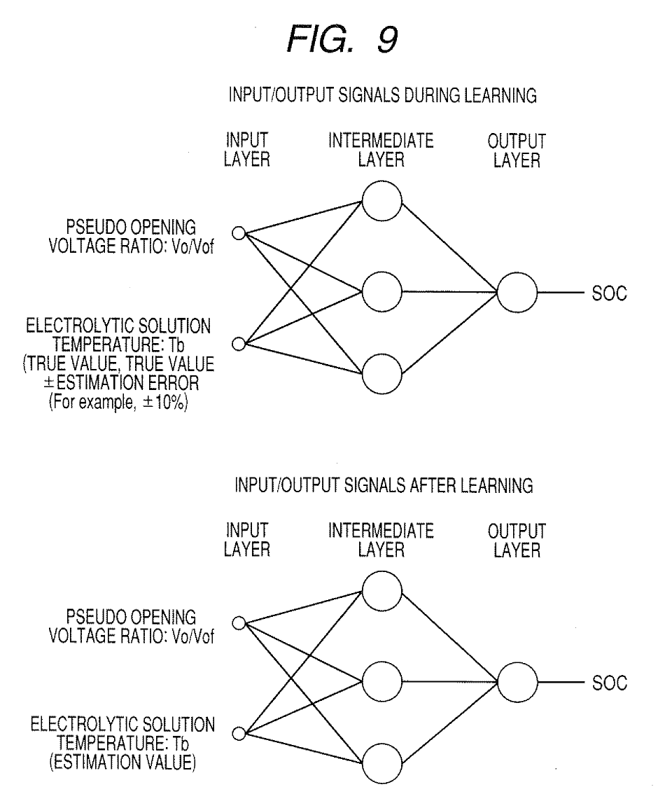

FIG. 9 is a block diagram showing the learning step of the neural network unit 107 and the SOC calculation by the neural network unit 107 after completion of the learning step according to the embodiment described above. The neural network unit 107 performs such a SOC calculation after completion of the learning step by the same method in the reference example described above.

### (SOC Calculation After Completion of the Learning Step)

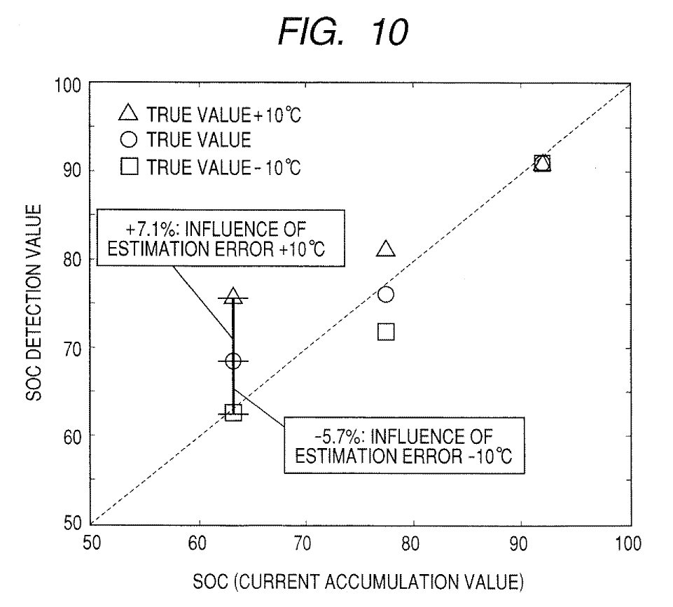

Next, a description will now be given of the SOC detection error when the neural network unit 107 inputs, after completion of the stufy step, the true value, the true value +10° C., and the true value −10° C. with reference to FIG. 10.

FIG. 10 is a characteristic view of the SOC errors at each temperature in the neural network unit 107 after completion of the learning step shown in FIG. 9. The pseudo opening voltage ratio of a same value is input into the neural network unit 107 at the true value, the value=true value +10° C., and the value=true value −10° C.

In FIG. 10, reference character “◯” indicates the true value, “Δ” denotes the true value +10° C., and “□” designates the true value −10° C.

The pseudo opening voltage ratio obtained per electrolytic solution temperature value is input into the neural network unit 107 as the input parameter.

In FIG. 10, the horizontal line indicates the SOC value obtained by the current accumulation, and the vertical line denotes the SOC detection value obtained by the neural network unit in the apparatus according to the embodiment or by the neural network unit according to the reference example described above.

It can be understood from FIG. 10 that the SOC detection value becomes +7.1% up when the temperature detection value having an estimation error larger by 10° C. than that when the electrolytic solution temperature estimation value is correctly input to the neural network unit 107 (in case of inputting the true value of 0° C.). Further, the SOC detection value becomes −5.7% down when the temperature detection value having an estimation error value which is smaller by 10° C. than that when the electrolytic solution temperature estimation value is correctly input to the neural network unit 107. Thus, it is possible to drastically decrease the detection error.

### (Explanation of Learning Each Battery)

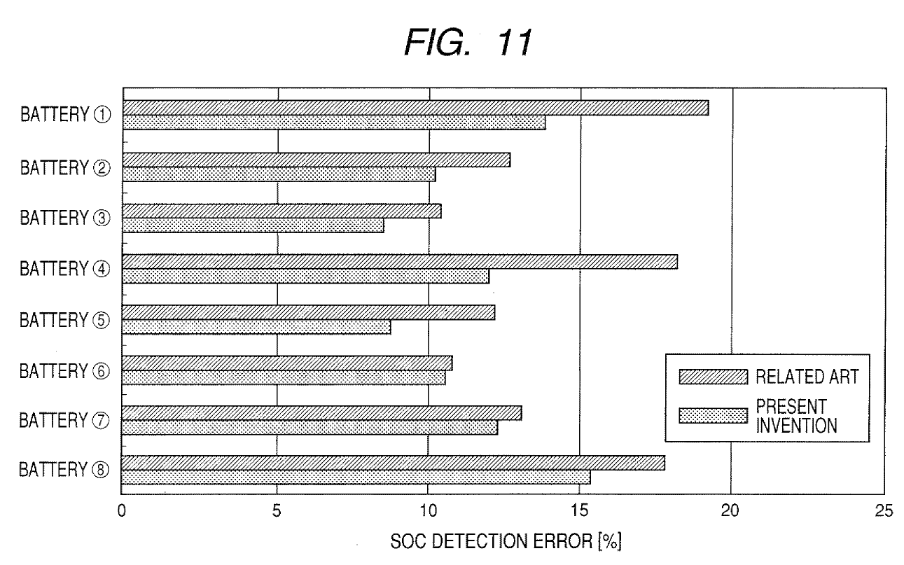

SOC detection errors between the embodiment of the present is invention and the reference example (as a related art) were measured using eight storage batteries \textcircled{1} to \textcircled{8} shown in FIG. 11 (each is a vehicular lead-acid battery) which have a different capacitance and a different deterioration level. FIG. 11 is a view showing the detection results of the SOC detection errors of those various type storage batteries, which were calculated by the neural network unit of the apparatus according to the embodiment and the reference example. It can be understood from FIG. 11, the apparatus using the neural network unit 107 according to the embodiment can drastically reduce the SOC detection error when compared with the related art reference example.

### (First Modification)

As shown in Table 2, in the learning step, the neural network unit 107 of the embodiment inputs the temperature true value, the temperature large value, and the temperature small value with a same weight as the input parameters. However, a probability of the temperature detection value, detected by the temperature sensor, near the temperature true value is larger than a probability of the value near the temperature large value or the temperature small value.

From this point of view, the number of the repeated learning steps for the temperature true value shown in Table 2 is greater than that of the temperature large or small value and input into the neural network unit 107 according to the first modification of the present invention. For example, in the first modification, the number of the learning step for the true value is set three times when compared with that for the temperature large or small value. This can further decrease the temperature detection error.

### (Second Modification)

Similar to first modification described above, as shown in Table 2, in the learning step, the neural network unit 107 of the embodiment inputs the temperature true value, the temperature large value, and the temperature small value with a same weight as the input parameters. However, a probability of the temperature detection value, detected by the temperature sensor, near the temperature true value is larger than a probability of the value near the temperature large value or the temperature small value.

From this point of view, the second modification has a configuration of the neural network unit in which the input cells in the input layer 201 is composed of a plurality of true temperature value input cells, a temperature large value cell through which the temperature large value is input, and a temperature small value cell for the learning step.

In the SOC calculation after completion of the learning step, the neural network unit 107 inputs the temperature detection values for those cells. The second modification described above can perform the same weighting for the input parameters like the first modification of the present invention.

### (Third Modification)

The embodiment and the first and second modifications according to the present invention described above use the neural network unit 107 capable of calculating the SOC of the storage battery. It is apparent that the neural network unit 107 outputs another output parameter regarding well-known internal state variables of the storage battery instead of the SOC.

### (Summarize)

In the method and apparatus according to the embodiment and the first and second modifications according to the present invention describe above, the neural network based calculation learns in advance the relationship between the storage battery temperature and the function values which are weighted using a temperature detection error and the SOC as the output parameter, in order to prevent the fluctuation of the SOC value as the output parameter of the neural network unit 107 by the temperature detection error, where the neural network unit 107 inputs as the input parameters, the temperature of the storage battery as the measurement target detected by the temperature sensor and the function value obtained by compensating such a storage battery temperature.

The concept of the present invention is not limited by the type of the detection target such as a storage battery, and further not limited by the types of those input parameters, such as a temperature sensor, to be supplied into the neural network unit of the apparatus. It is therefore possible to use a function value using a sensor output as an input variable of a predetermined function as one of the input parameters for the neural network unit.

While specific embodiments of the present invention have been described in detail, it will be appreciated by those skilled in the art that various modifications and alternatives to those details could be developed in light of the overall teachings of the disclosure. Accordingly, the particular arrangements disclosed are meant to be illustrative only and not limited to the scope of the present invention which is to be given the full breadth of the following claims and all equivalent thereof.

What is claimed is:

1. A method of calculating state variables of a secondary battery comprising:
learning, for a predetermined neural network, a plurality of combinations of true values of state variables of the secondary battery by inputting plural times those combinations into the neural network, where the state variables of the secondary battery including a secondary battery temperature are input parameters, and an internal state variable of the secondary battery is an output parameter,
periodically detecting the state variables of the secondary battery; and
estimating the output parameter of the secondary battery by inputting detection values of the state variables of the secondary battery to the neural network after the learning,
wherein in the learning for the neural network, a temperature small value which is smaller than the temperature true value of the secondary battery, a temperature large value which is larger than the temperature true value of the secondary battery, and the temperature true value are input into the neural network, and
an absolute value of a difference between the temperature small value and the temperature true value, and an absolute value of a difference between the temperature large value and the temperature true value are so set that the absolute value of a difference is approximately equal to an absolute value of a maximum detection error of the temperature sensor.

2. The method of calculating state variables of a secondary battery according to claim 1, wherein in the learning by the neural network, the number of inputs of the temperature true value into the neural network is substantially larger than the number of inputs of the temperature small value and the temperature large value to the neural network.

3. The method of calculating state variables of a secondary battery according to claim 1, wherein the state variables of the secondary battery include an opening voltage ratio in addition to the secondary battery temperature.

4. The method of calculating state variables of a secondary battery according to claim 2, wherein the state variables of the secondary battery include an opening voltage ratio in addition to the secondary battery temperature.

5. An apparatus for estimating state variables of an estimation target based on a neural network based calculation, comprising:
a sensor configured to detect a state variable of the estimation target and to output the detected state variable as an output signal of the sensor; and
a neural network unit configured to input one of the output signal of the sensor and a function value of a predetermined function of the output signal of the sensor, to perform a neural network based calculation, and to output a predetermined state variable of the estimation target as an output parameter thereof which is different from the detection state variables of the estimation target,
wherein before performing the neural network based calculation, the neural network unit learns plural times a combination of the output signal of the sensor or a true value of the function value of the predetermined function of the output signal of the sensor and a true value of the predetermined state variable of the estimation target, and further learns a relationship between the true value of the predetermined state variable of the estimation target and values obtained by adding/subtracting a predetermined sensor detection error value to/from the true value of one of the output signal of the sensor and the function value of the output signal of the sensor.

6. The method of calculating state variables of a secondary battery according to claim 1, wherein the temperature large value is larger than the temperature true value of the secondary battery by 10% of the temperature true values and the temperature small value is smaller than the temperature true value of the secondary battery by 10% of the temperature true value.

7. The apparatus for estimating state variables of an estimation target based on a neural network based calculation according to claim 5, wherein the predetermined sensor detection error value is within a range of ±10% of the true value of the output signal of the sensor.
